(19) United States
(12) Patent Application Publication
(10) Pub. No.: US 2003/0122173 A1
(43) Pub. Date: Jul. 3, 2003

(54) Package for a non-volatile memory device including integrated passive devices and method for making the same

(76) Inventors: Eleanor P. Rabadam, Folsom, CA (US); Michael J. Walk, Mesa, AZ (US); Milan Keser, Chandler, AZ (US)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 10/039,454

(22) Filed: Dec. 28, 2001

(51) Int. Cl. H01L 27/108

(52) U.S. Cl. 257/298

(57) ABSTRACT

Briefly, in accordance with one embodiment of the invention, a memory device package includes an integrated circuit die having a memory array and at least one passive component mounted to the integrated circuit component.

### BACKGROUND

Memory devices such as, for example, non-volatile memory devices often involve the use of programming/erasing voltage potentials that are typically different that the normal operating voltage potentials. As a result, the memory devices may be connected to additional circuitry that generates and regulates the voltage potentials used to program or erase the memory device. However, the additional circuitry may increase the cost associated with the memory devices. The additional circuits and components may also affect the reliability of the memory device as there as more components involved who failure may result in a failure of the operation of the memory.

Thus, there is a continuing need for better ways to package memory devices.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

The sole FIGURE is an enlarged cross-sectional view of a package for an integrated circuit in accordance with an embodiment of the present invention.

It will be appreciated that for simplicity and clarity of illustration, elements illustrated in the FIGURE have not necessarily been drawn to scale. For example, the dimensions of some of the elements are exaggerated relative to other elements for clarity.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

In the following description and claims, the terms “coupled” and “connected,” along with their derivatives, may be used. It should be understood that these terms are not intended as synonyms for each other. Rather, in particular embodiments, “connected” may be used to indicate that two or more elements are in direct physical or electrical contact with each other. “Coupled” may mean that two or more elements are in direct physical or electrical contact. However, “coupled” may also mean that two or more elements are not in direct contact with each other, but yet still co-operate or interact with each other.

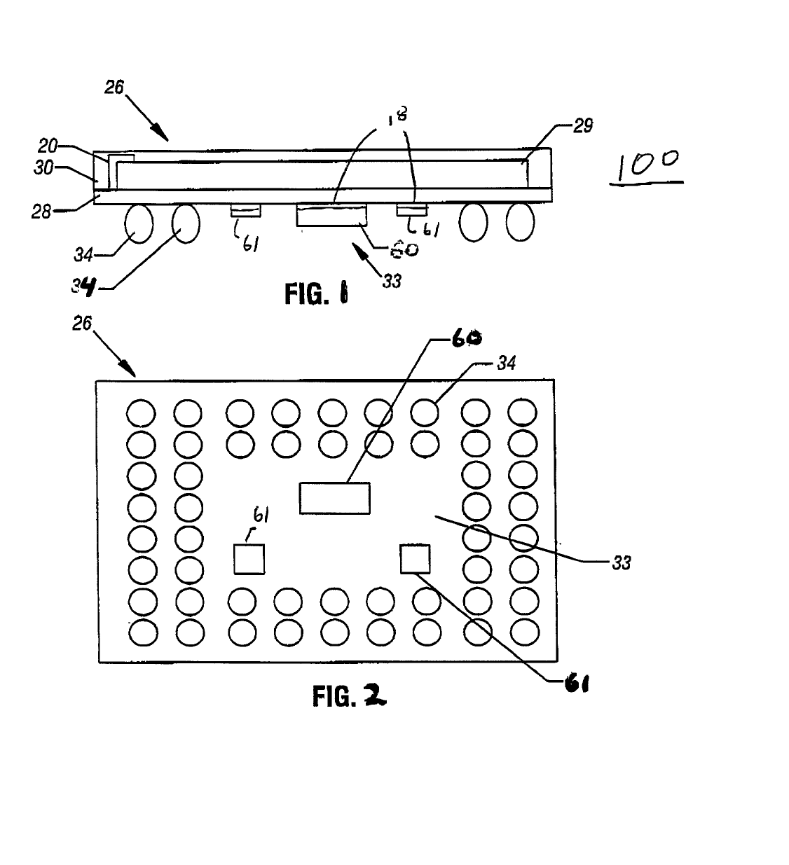

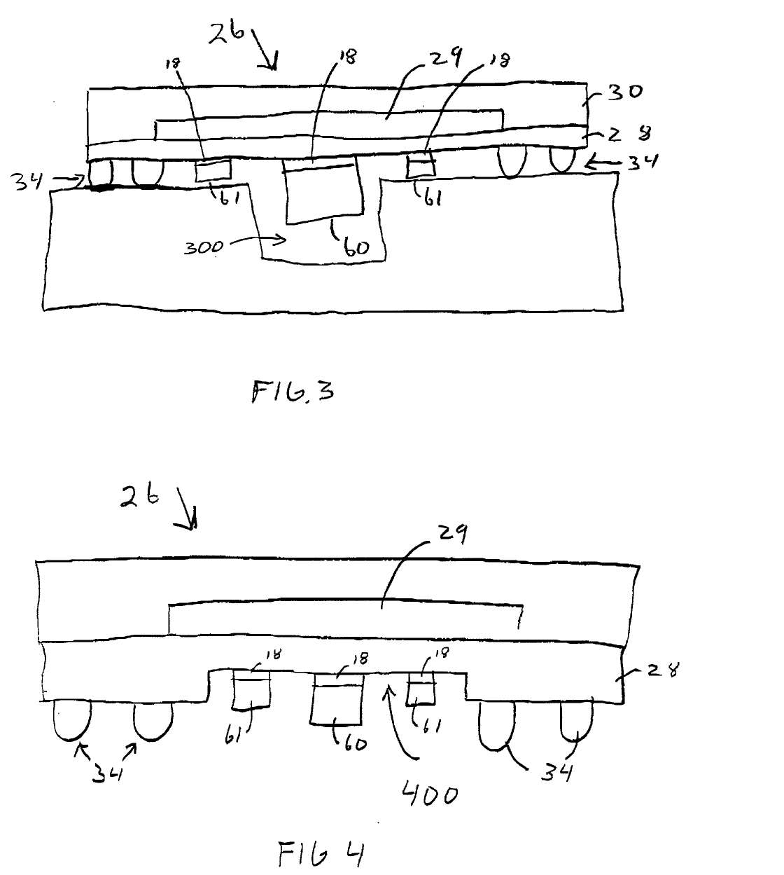

Turning to FIG. 1, an embodiment 100 in accordance with the present invention is described. A ball grid array (BGA) package 10 may include a substrate 12 that may be electrically coupled to external circuitry using a multiplicity of solder balls 25. It should be understood that the scope of the present invention is not limited to BGA packages, as other packages may be alternatively used.

Package 10 may contain an integrated circuit die 14 attached to the substrate 12, for example using a suitable adhesive 16. Adhesive 16 may comprise a non-conductive material so as to provide electrical isolation between substrate 12 and integrated circuit die 14. Alternatively, adhesive 16 may comprise a conductive material so as to electrically couple integrated circuit 14 to substrate 12 or the underlying solder balls 25.

Although the scope of the present invention is not limited in this respect, integrated circuit die 14 may include a non-volatile memory arrays such as an electrically programmable read-only memories (EPROMs), electrically erasable and programmable read only memories (EEPROMs), single-bit flash memory, multi-bit flash memory, etc.

In one embodiment, all or a portion of a voltage regulator circuit may be formed within package 10. The voltage regulator may be used to provide voltage potentials to be used during the operation of integrated circuit die 14. For example, although the scope of the present invention is not limited in this respect, the voltage regulator may provide voltage potentials to program and/or erase the non-volatile memory within integrated circuit die 14.

Although the scope of the present invention is not limited in this respect passive components 16a and 16b may be formed and molded within package 10. For example passive components 16a and 16b may include components such as capacitors, inductors, resistive elements, or other integrated components associated with charge pump circuitry, voltage regulator circuitry, etc. Although this list is not meant to be exhaustive as any active or passive device may be mold in package 10 if desired.

Passive components 60-61 may be mounted or attached to the upper surface of integrated circuit die 14, for example using an adhesive 18. Adhesive may comprise a non-conductive material such as, for example, an epoxy so as to provide electrical isolation between passive components 60 and 61. Although the scope of the present invention is not limited in this respect, for in alternative embodiments, adhesive 18 may comprise some conductive material (e.g. solder paste) so as to electrically couple passive components 60-61 to integrated circuit die 14. The thickness of adhesive layer may be varied as desired, but may be less than about 0.1 millimeters so as to reduce the overall thickness of package 10.

[Please feel free to elaborate on the epoxy process]

Wire bonds 20 may be formed between passive components 60-61 and substrate 12, or between integrated circuit die 14 and substrate 12 as shown in FIG. 1. Alternatively, or in addition to, wire bonds may be formed between passive components 60-61 and integrated circuit die 14. Wire bonds 20 may provide electrical connection to integrated circuit die 14, substrate 12 and/or any of the underlying solder balls 25.

Thereafter, integrated circuit die 14 and passive components 60-61 may be molded in a non-conductive encapsulant 24 to form a molded array package (MAP), although the scope of the present invention is not limited in this respect. Although only a few passive components are shown in FIG. 1, it should be understood that in alternative embodiments just one or all the passive components associated with the operation of integrated circuit die 14 may included within package 10. In addition, it should be understood that the scope of the present invention is not limited in application to only non-volatile memory devices, or only to memory devices in general.

Accordingly, the embodiment illustrated in the figure demonstrates a power supply in package (PSIP arrangement where at least portions of the circuitry or components associated with the operation of integrated circuit die 14 may be mounted to integrated circuit die 14 and within package 10. Package 10 may substantially maintain the form factor of a corresponding non-PSIP packages (e.g. separate packages for the memory device, for the passive components, and for the voltage regulator) so that package 10 may fit within the space allocated on boards for corresponding non-PSIP packages that perform substantially the same features. As a result, a compact package 10 may be achieved that has lower manufacturing costs while substantially maintaining the form factor of corresponding (but more expensive) non-PSIP packages.

While certain features of the invention have been illustrated and described herein, many modifications, substitutions, changes, and equivalents will now occur to those skilled in the art. It is, therefore, to be understood that the appended claims are intended to cover all such modifications and changes as fall within the true spirit of the invention.

1. A non-volatile memory package comprising:
a substrate having a first surface and a second surface;
an integrated circuit die including a memory array mounted to the first surface of the substrate; and
a passive component mounted to the second surface of the substate.

2. The non-volatile memory package of claim 1, wherein the passive component is electrically coupled to the integrated circuit die.

3. The non-volatile memory package of claim 1, further comprising an array of solder balls mounted to the substrate.

4. The non-volatile memory package of claim 3, wherein the passive component is located centrally within the array of solder balls.

5. The non-volatile memory package of claim 4, wherein the passive component has a height less than a height of the solder balls.

6. The non-volatile memory package of claim 1, wherein the passive component is at least a portion of a voltage regulator circuit coupled to the integrated circuit die.

7. The non-volatile memory package of claim 1, wherein the substrate comprises a cavity and at least a portion of the passive component lies within the cavity.

8. The non-volatile memory package of claim 7, further comprising an array of solder balls mounted to the substrate, wherein the passive component has a height less than a height of the solder balls.

10. The non-volatile memory package of claim 1, wherein the passive component is mounted to the substrate with an epoxy material.

11. The non-volatile memory package of claim 10, wherein the epoxy material between the passive component and the substrate is less than about 0.1 millimeters in thickness.

12. The non-volatile memory package of claim 1, wherein the passive component is mounted to the substrate with a conductive material.

13. The non-volatile memory package of claim 1, wherein the passive component includes a capacitor or an inductor.

14. The non-volatile memory package of claim 1, wherein the integrated circuit die includes a flash memory array.

13. A method comprising:
forming a substrate;
mounting an integrated circuit die on said substrate;
mounting a passive component overly the substrate; and
electrically coupling the passive component to at least a portion of the integrated circuit die.

14. The method of claim 13, further comprising adhesively attaching the passive component to the integrated circuit die.

15. The method of claim 14, further comprising adhesively attaching the passive component to the integrated circuit die with a non-conductive adhesive.

16. The method of claim 13 including wire bonding the passive component to the substrate.

17. The method of claim 13 including wire bonding the passive component to the integrated circuit die.

18. A method comprising:
molding an integrated circuit die and at least one passive component of a voltage regulator circuit into a package, the integrated circuit die including a non-volatile memory array.

19. The method of claim 18, further comprising mounting the at least one passive component to the integrated circuit die.

20. The method of claim 18, further comprising forming a wire bond to electrically couple the at least one passive component and the integrated circuit.
